(19) United States
(12) Patent Application Publication
(10) Pub. No.: US 2005/0193950 A1
(43) Pub. Date: Sep. 8, 2005

(54) Supporting module and alignment apparatus for a substrate

(75) Inventor: Moon-Chul Cho, Gyeonggi-do (KR)

Correspondence Address: David W. Held;MacPHERSON KWOK CHEN & HEID LLP, Suite 226, 1762 Technology Drive, San Jose, CA, 95110, US

(73) Assignee: Samsung Electronics Co., Ltd., Suwon-si (KR)

(21) Appl. No.: 11/070,023

(22) Filed: Mar. 1, 2005

(30) Foreign Application Priority Data
Mar. 2, 2004 (KR) 2004-14031

(51) Int. Cl. H05B 3/68; C23C 16/00

(52) U.S. Cl. 118/725; 219/444.1

(57) ABSTRACT

A supporting module is used to support a substrate in an alignment apparatus for aligning the substrate. The supporting module includes one or more supporting bodies, each supporting body having a hole on an upper portion of the supporting body. A supporting ball is partially inserted into the hole such that an exposed portion of the supporting ball makes contact with the substrate supported by the supporting module. As the substrate is laterally translated, static friction between the substrate and the supporting ball causes the supporting ball to rotate. An auxiliary ball is also provided in the supporting body to make contact with the supporting ball. The auxiliary ball rotates using a friction between the supporting ball and the auxiliary ball. This arrangement prevents scratching, cracking or other damage that would be caused to the substrate by dynamic friction between the substrate and a non-rotatable supporting module.

### CROSS-REFERENCE TO RELATED APPLICATIONS

The present application claims priority from Korean Patent Application No. 2004-14031, filed on Mar. 2, 2004, the disclosure of which is hereby incorporated herein by reference in its entirety.

### BACKGROUND

1. Field of the Invention

The present invention relates to a supporting module for supporting a substrate and an alignment apparatus for aligning the substrate. More particularly, the present invention relates to a supporting module for supporting a substrate for a liquid crystal display (LCD) apparatus and an alignment apparatus for aligning a substrate, which has the supporting module.

2. Description of the Related Art

An LCD apparatus, in general, is manufactured by performing a plurality of manufacturing processes on a substrate. The manufacturing processes of the LCD apparatus are typically automated to increase the efficiency of the manufacturing process. In a predetermined unit process, the substrate may be unloaded using an unloading unit so that the unloaded substrate is in a cassette, and the substrate in the cassette is transported to another apparatus for another unit process.

When the unloaded substrate is in the cassette, the substrate is aligned using an alignment apparatus for aligning the substrate. In addition, prior to the transportation of the substrate in the cassette, the substrate is also aligned using the alignment apparatus for aligning the substrate.

The alignment apparatus for aligning the substrate includes a supporting module that contacts and supports the substrate for the LCD apparatus, and an aligning module that aligns the substrate for the LCD apparatus. When the substrate for the LCD apparatus is aligned, the aligning module moves the substrate relative to the supporting module. As the substrate is moved by the aligning module, the dynamic friction between the supporting module and the substrate for the LCD apparatus may result in scratching or cracking of the surface of the substrate for the LCD apparatus. Therefore, the substrate for the LCD apparatus may be damaged.

### SUMMARY

In accordance with the present invention, a supporting module for supporting a substrate for a liquid crystal display (LCD) apparatus is provided.

In accordance with the present invention, an alignment apparatus for aligning a substrate and having the above-mentioned supporting module is also provided.

A supporting module in accordance with an exemplary embodiment of the present invention includes a supporting body, a supporting ball and an auxiliary ball. The supporting module supports the substrate. The supporting body has a hole on an upper portion of the supporting body. The supporting ball is partially inserted into the hole such that the supporting ball is partially exposed through the hole. During operation, the exposed portion of the supporting ball makes contact with the substrate. The friction between the substrate and the supporting ball causes the supporting ball to rotate as the substrate is moved relative to the supporting module. The rotation of the supporting ball helps to prevent damage to the substrate caused by static friction between the two moving parts. The auxiliary ball is rotatably contained in the supporting body such that the auxiliary ball makes contact with the supporting ball. As the supporting ball rotates due to the movement of the substrate, the auxiliary ball also rotates as a result of the friction between the supporting ball and the auxiliary ball.

An alignment apparatus for aligning a substrate in accordance with an exemplary embodiment of the present invention includes a supporting module and an aligning module. The supporting module comprises a supporting body, a supporting ball and an auxiliary ball. The supporting body supports the substrate, as described above. The aligning module aligns the loaded substrate, which is supported by the supporting module.

Therefore, when the substrate is transported, the supporting ball that makes contact with the substrate rotates in a direction substantially parallel with a direction of translation of the substrate so that the friction between the supporting module and the substrate is decreased, thereby preventing damage of the substrate.

### BRIEF DESCRIPTION OF THE DRAWINGS

The above and other advantages of the present invention will become more apparent by describing in detail exemplary embodiments thereof with reference to the accompanying drawings, in which:

FIG. 1 is a cross-sectional view showing an apparatus for manufacturing an LCD apparatus in accordance with an exemplary embodiment of the present invention;

FIG. 2 is a perspective view showing an alignment apparatus for aligning a substrate in a loader or an unloader of FIG. 1;

FIG. 3 is a cross-sectional view showing a supporting module of FIG. 2; and

FIGS. 4A and 4B are cross-sectional views showing a method of aligning the substrate using the alignment apparatus of FIG. 2.

### DETAILED DESCRIPTION

It should be understood that the exemplary embodiments of the present invention described below may be varied and modified in many different ways without departing from the inventive principles disclosed herein, and the scope of the present invention is therefore not limited to these particular embodiments. Rather, these embodiments are provided so that this disclosure will be through and complete, and will fully convey the invention to those skilled in the art by way of example and not of limitation.

Hereinafter, embodiments present invention will be described in detail with reference to the accompanying drawings.

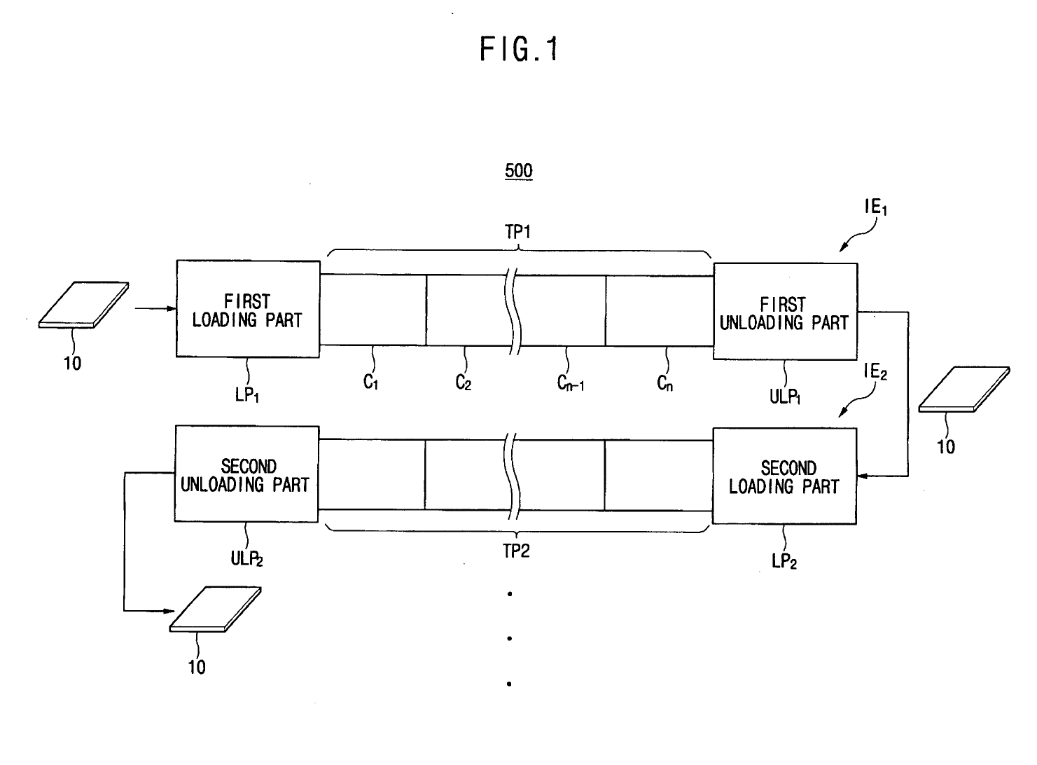

FIG. 1 is a cross-sectional view showing an apparatus for manufacturing an LCD apparatus in accordance with an exemplary embodiment of the present invention.

Referring to FIG. 1, the apparatus for manufacturing the LCD apparatus includes a plurality of in-line devices IE1, IE2, . . . for performing a plurality of manufacturing processes, respectively. For example, a substrate 10 for the LCD apparatus is processed in a first in-line device IE1, and the substrate 10 for the LCD apparatus is then transported to a second in-line device IE2 that is adjacent to the first in-line device IE1. The substrate 10 for the LCD apparatus is then transported from the second in-line device IE2 to a third in-line device (not shown) adjacent to the second in-line device IE2. The above-mentioned processes may be repeated using the in-line devices.

The first in-line device IE1 includes a first processing part TP1, a first loading part LP1 and a first unloading part ULP1. The first processing part TP1 performs a predetermined unit process on the substrate 10 for the LCD apparatus. The first loading part LP1 loads the substrate 10 for the LCD apparatus onto the first processing part TP1. The first unloading part ULP1 unloads the substrate 10 for the LCD apparatus from the first processing part TP1. The first processing part TP1 has a plurality of processing chambers C1, C2, . . . , Cn-1, Cn. In this exemplary embodiment, the number of the processing chambers C1, C2, . . . , Cn-1, Cn in the first processing part is ‘n’, wherein ‘n’ is a whole number.

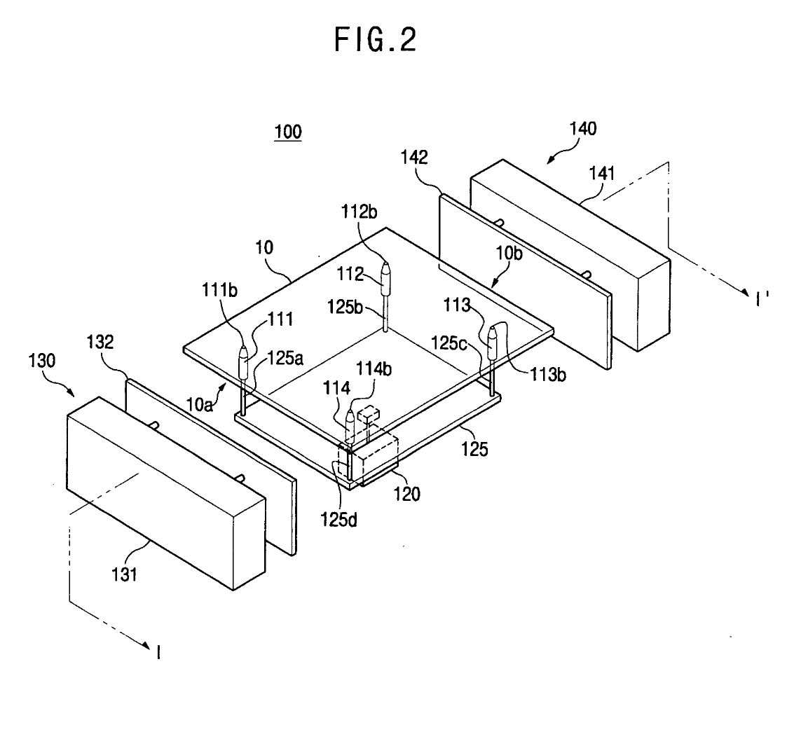

The substrate 10 for the LCD apparatus, which is processed in the first in-line device IE1, is aligned before being transported to the second in-line device IE2 by the first unloading part ULP1 or after being transported to a second loading part UP2 of the second in-line device. That is, the first unloading part ULP1 or the second loading part UP2 includes an alignment apparatus 100 shown in FIG. 2 for aligning the substrate 10 for the LCD apparatus.

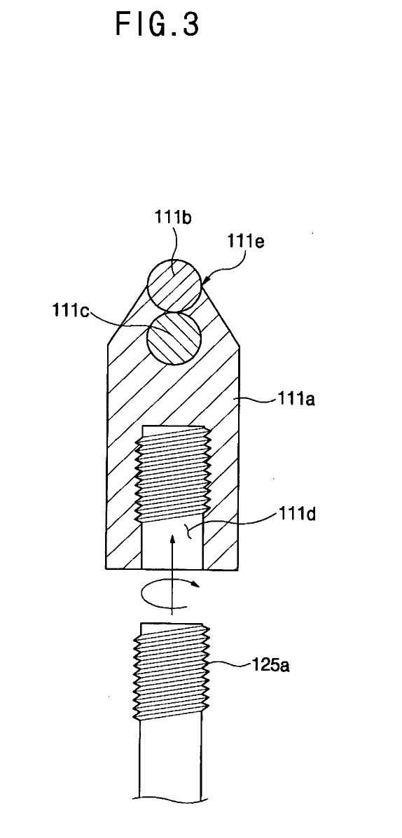

FIG. 2 is a perspective view showing an alignment apparatus for aligning a substrate in a loader or an unloader of FIG. 1. FIG. 3 is a cross-sectional view showing a supporting module in the alignment apparatus of FIG. 2.

Referring to FIGS. 2 and 3, the alignment apparatus 100 for aligning the substrate 10 for the LCD apparatus includes a first supporting module 111, a second supporting module 112, a third supporting module 113, a fourth supporting module 114, an elevator 120, a first aligning module 130 and a second aligning module 140. The first to fourth supporting modules 111, 112, 113 and 114 support the substrate 10 for the LCD apparatus. The elevator 120 controls a vertical movement of the first to fourth supporting modules 111, 112, 113 and 114. The first and second aligning modules 130 and 140 align the substrate 10 for the LCD apparatus.

The first to fourth supporting modules 111, 112, 113 and 114 include a first supporting ball 111b, a second supporting ball 112b, a third supporting ball 113b and a fourth supporting ball 114b, respectively. The first to fourth supporting balls 111b, 112b, 113b and 114b make contact with a lower surface of the substrate 10 for the LCD apparatus. The first to fourth supporting balls 111b, 112b, 113b and 114b may rotate. In this exemplary embodiment, the first to fourth supporting balls 111b, 112b, 113b and 114b rotate in a direction substantially parallel with a transportation direction of the substrate 10 for the LCD apparatus. Each of the first to fourth supporting balls 11b, 112b, 113b and 114b may comprise a ceramic, a synthetic resin, etc.

Therefore, the friction between the substrate 10 for the LCD apparatus and each of the first to fourth supporting balls 111b, 112b, 113b and 114b is decreased to prevent scratching, cracking or other damage to the substrate 10.

Referring to FIG. 3, the first supporting module 111 includes a first supporting body 111a, a first supporting ball 111b and a first auxiliary ball 111c. The first to fourth supporting modules 111, 112, 113 and 114 have substantially similar shapes to one another, and any further explanation of the second to forth supporting modules 112, 113 and 114 will be omitted.

An upper portion of the first supporting body 111a is positioned adjacent to the substrate 10 for the LCD substrate. A hole 111e is formed at the upper portion of the first supporting body 111a. An engaging recess 111d is formed at a lower portion of the first supporting body 111a so that the first supporting body 111a is coupled with a first connecting rod 125a. In this exemplary embodiment, the first supporting body 111a comprises a threaded bore that receives a threaded first connecting rod 125a mounted to the plate 125. Thus, a height of the first supporting body 111a relative to the plate 125 may be controlled using an axial rotation of the first connecting rod 125a.

The first supporting ball 111b is inserted into the hole 111e, and the first supporting ball 111b is partially exposed through the hole 111e so that the exposed portion of the first supporting ball 111b makes contact with the substrate 10 for the LCD apparatus. When the substrate 10 for the LCD apparatus is translated relative to the first supporting module 111, the friction between the bottom surface of the substrate 10 and the first supporting ball 111b causes the first supporting ball 111b to rotate. This rotation reduces or eliminates the amount of dynamic friction between the substrate 10 and the first supporting module 111, thereby preventing damage to the substrate 10 for the LCD apparatus. The first auxiliary ball 111c is in the first supporting body 111a, and makes contact with the first supporting ball 111b. The first auxiliary ball 111c rotates using a friction between the first supporting ball 111b and the first auxiliary ball 111c so that the first supporting ball 111b may easily rotate. The first auxiliary ball 111c reduces the rotational resistance of the first supporting ball 111b. In this exemplary embodiment, two pieces having recesses are combined each other to form the supporting body 111a, and the first auxiliary ball 111c is inserted into the recesses of the pieces before the pieces are combined. Alternatively, the first auxiliary ball 111c may inserted into a recess of the supporting body 111a, and the recess may be partially covered so that the auxiliary ball 111c is in the supporting body 111a.

Referring again to FIG. 2, the elevator 120 is connected to a plate 125 to control vertical movement of the plate 125. The first to fourth supporting modules 111, 112, 113 and 114 are coupled to the plate 125 through the first connecting rod 125a, a second connecting rod 125b, a third connecting rod 125c and a fourth connecting rod 125d, respectively. The elevator 120 controls the vertical movement of the plate 125 with respect to the substrate 10 for the LCD apparatus to control vertical movements of the first to fourth supporting modules 111, 112, 113 and 114.

When the substrate 10 for the LCD apparatus is loaded on the alignment apparatus 100 for aligning the substrate 10, the elevator 120 elevates the plate 125 so that the first to forth supporting modules 111, 112, 113 and 114 are elevated. When the substrate 10 for the LCD apparatus is unloaded from the alignment apparatus 100 for aligning the substrate, the elevator 120 lowers the plate 125 so that the first to fourth supporting modules 111, 112, 113 and 114 are lowered.

The first and second aligning modules 130 and 140 are positioned adjacent to a first end portion 10a and a second end portion 10b of the substrate 10 for the LCD apparatus, which is supported by the first to fourth supporting modules 111, 112, 113 and 114. In this exemplary embodiment, the second end portion 10b is opposite to the first end portion 10a.

The first aligning module 130 includes a first alignment plate 132 and a first control member 131. The first alignment plate 132 is adjacent to the first end portion 10a of the substrate 10 for the LCD apparatus. The first control member 131 controls horizontal movement of the first alignment plate 132. The second aligning module 140 includes a second alignment plate 142 and a second control member 141. The second alignment plate 142 is adjacent to the second end portion 10b of the substrate 10 for the LCD apparatus. The second control member 141 controls horizontal movement of the second alignment plate 142.

When the substrate 10 for the LCD apparatus is supported by the first to fourth supporting modules 111, 112, 113 and 114, the first and second aligning modules 130 and 140 align the substrate 10 by using the first and second control members 131 and 141 to move the first and second alignment plates 132 and 142 toward the substrate 10 for the LCD apparatus. The first and second alignment plates 132 and 142 then make contact with the first and second end portions 10a and 10b of the substrate 10 for the LCD apparatus, respectively, so that the substrate 10 for the LCD apparatus is aligned with respect to the alignment apparatus 100 for aligning the substrate 10 for the LCD apparatus.

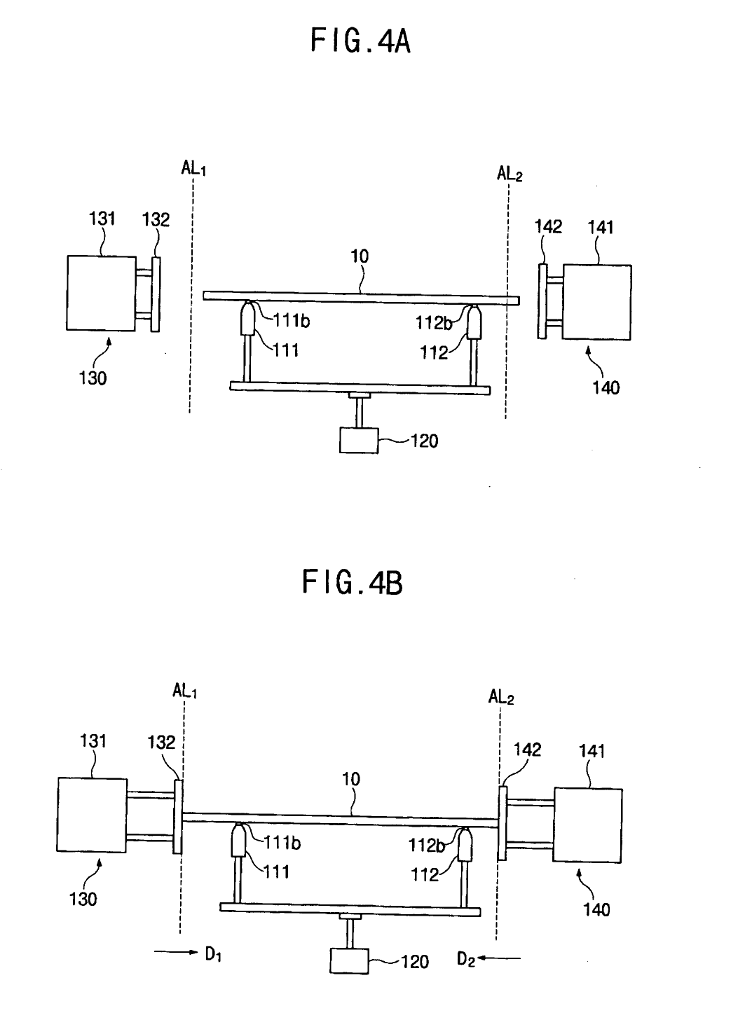

FIGS. 4A and 4B are cross-sectional views showing a method of aligning the substrate using the alignment apparatus for aligning the substrate of FIG. 2. FIGS. 4A and 4B are cross-sectional views taken along a line I-I′ of FIG. 2.

Referring to FIG. 4A, the substrate 10 for the LCD apparatus is supported by the first, second, third and fourth supporting modules 111-114 (only the first and second supporting modules 111 and 112 are shown in FIG. 4A), and the substrate 10 is misaligned with respect to a first aligning line AL1 and a second aligning line AL2 that is spaced apart from the first aligning line AL1 by a horizontal width of the substrate 10 for the LCD apparatus. The first and second aligning lines AL1 and AL2 represent the desired horizontal position of the substrate 10. The misaligned substrate 10 for the LCD apparatus is aligned using the first and second aligning modules 130 and 140.

Referring to FIG. 4B, the first control member 131 translates the first alignment plate 132 toward the substrate 10 for the LCD apparatus in a first direction D1 so that the first alignment plate 132 is aligned with the first aligning line AL1. In addition, the second control member 141 translates the second alignment plate 142 toward the substrate 10 for the LCD apparatus in a second direction D2 so that the second alignment plate 142 is aligned with the second aligning line AL2.

As the second control member 141 translates the second alignment plate 142 in the second direction D2 towards the second aligning line AL2, the second alignment plate 142 makes contact with the second end portion 10b of the substrate 10 for the LCD apparatus. Therefore, the second alignment plate 142 transports the substrate 10 for the LCD apparatus in the second direction D2 so that the first and second end portions 10a and 10b are aligned with the first and second aligning lines AL1 and AL2, respectively. The substrate 10 for the LCD apparatus is thus aligned with respect to the first aligning line AL1 and the second aligning line AL2.

As the substrate 10 is moved by the first and second aligning modules 130 and 140, the first supporting ball 111b of the first supporting module 111 and the second supporting ball 112b of the second supporting module 112 rotate in substantially equal directions to each other. Therefore, the friction between the substrate 10 for the LCD apparatus and each of the first and second supporting modules 111 and 112 is decreased to prevent scratching or cracking of the substrate 10 for the LCD apparatus.

In accordance with embodiments of the present invention, when the substrate is transported, the supporting ball that makes contact with the substrate rotates using the friction between the substrate and the supporting ball. In addition, the auxiliary ball that makes contact with the supporting ball rotates with the supporting ball so that the supporting ball may easily rotate.

Therefore, the supporting ball rotates in a direction substantially parallel with the transportation direction to decrease a friction between the supporting module and the substrate, thereby preventing scratching or cracking of the substrate.

This invention has been described with reference to the exemplary embodiments. It is evident, however, that many alternative modifications and variations will be apparent to those having skill in the art in light of the foregoing description. Accordingly, the present invention embraces all such alternative modifications and variations as fall within the spirit and scope of the appended claims.

1. A supporting module of an alignment apparatus for aligning a substrate, the supporting module comprising:
a supporting body that supports the substrate, the supporting body having a hole on an upper portion of the supporting body; and
a rotatable supporting ball partially received in the hole such that an exposed portion of the supporting ball makes contact with the substrate supported by the supporting module.

2. The supporting module of claim 1, further comprising:
a rotatable auxiliary ball in the supporting body contacting the supporting ball such that rotation of the supporting ball causes rotation of the auxiliary ball.

3. The supporting module of claim 1, wherein the supporting ball comprises a ceramic.

4. The supporting module of claim 1, further comprising a connecting rod combined with the supporting body to control a height of the supporting body.

5. The supporting module of claim 4, wherein the connecting rod is screwed with the supporting body.

6. An alignment apparatus for aligning a substrate comprising:
a supporting module including:
a supporting body that supports the substrate, the supporting body having a hole on an upper portion of the supporting body; and
a rotatable supporting ball partially received in the hole such that an exposed portion of the supporting ball makes contact with the substrate supported by the supporting module; and
an aligning module that aligns the loaded substrate.

7. The alignment apparatus of claim 6, wherein the supporting module further comprises:
a rotatable auxiliary ball in the supporting body contacting the supporting ball such that rotation of the supporting ball causes rotation of the auxiliary ball.

8. The alignment apparatus of claim 6, wherein the aligning module comprises:
a first alignment plate adjacent to a first end portion of the substrate;
a first control member that controls a horizontal movement of the first alignment plate with respect to the substrate;
a second alignment plate adjacent to a second end portion of the substrate, the second end portion corresponding to the first end portion; and
a second control member that controls a horizontal movement of the second alignment plate with respect to the substrate.

9. The alignment apparatus of claim 8, wherein the first and second alignment plates guide the first and second end portions to a first aligning line and a second alignment line that is spaced apart from the first alignment line by a width of the substrate, respectively.

10. The alignment apparatus of claim 6, further comprising an elevator connected to the supporting module to control a vertical movement of the supporting module with respect to the substrate.

11. The supporting module of claim 10, further comprising a plurality of supporting modules, and wherein each of the supporting modules further comprises a connecting rod combined with the supporting body to control a height of the supporting body.

12. The supporting module of claim 11, wherein the connecting rod is screwed with the supporting body.

13. A method of aligning a substrate, comprising:
positioning the substrate on a plurality of supporting bodies of a supporting module, wherein each supporting body comprises a rotatable supporting ball contacting the substrate; and
translating the substrate in a horizontal direction relative to the plurality of supporting bodies such that the translation of the substrate causes rotation of the supporting balls.

14. The method of claim 13, wherein:
said translating the substrate in the horizontal direction comprises applying a horizontal force onto a first edge of the substrate with an alignment plate.

15. The method of claim 13, further comprising:
adjusting a vertical position of the supporting module relative to the substrate.

16. The method of claim 13, further comprising:
processing the substrate for use in a liquid crystal display apparatus.

17. The method of claim 13, wherein:
said rotation of the supporting balls causes rotation of auxiliary balls in the plurality of supporting bodies.
